(19) United States
(12) Patent Application Publication
(10) Pub. No.: US 2026/0106621 A1
(43) Pub. Date: Apr. 16, 2026

(54) CLOCK DIVIDER AND METHOD OF CONTROLLING SAME

(71) Applicant: ITDA SEMICONDUCTOR CO., LTD., Hwaseong-si (KR)

(72) Inventors: Ahchan KIM, Hwaseong-si (KR); Hoyeon JEON, Seongnam-si (KR); Ingyu KIM, Hwaseong-si (KR)

(73) Assignee: ITDA SEMICONDUCTOR CO., LTD., Hwaseong-si (KR)

(21) Appl. No.: 19/255,730

(22) Filed: Jun. 30, 2025

(30) Foreign Application Priority Data
Jul. 22, 2024 (KR) 10-2024-0096475
Jul. 2, 2024 (KR) 10-2024-0086592

(51) Int. Cl. H03L 7/099; H03L 7/08

(52) U.S. Cl. CPC H03L 7/0992; H03L 7/0802

(57) ABSTRACT

Disclosed are a clock divider and a method of controlling the same to ensure that an output clock of the clock divider is in a low level state during a retention signal transition period such that a retention operation can be performed smoothly. The clock divider includes a counter configured to count an input clock and generate a counter output for dividing the input clock, an output clock generator configured to generate clock edges according to the counter output and generate an output clock divided from the input clock, and a state machine configured to control the counter such that the output clock is in a low level during a retention signal transition period according to a clock low request from a power management unit.

### CROSS-REFERENCE TO RELATED APPLICATION

This application claims the benefit of and priority to Korean Patent Application No. 10-2024-0086592, filed on July 2, 2024, and Korean Patent Application No. 10-2024-0096475, filed on July 22, 2024, the entire disclosure(s) of which is hereby incorporated herein by reference in its entirety.

### STATEMENT REGARDING GOVERNMENT SPONSORED RESEARCH OR DEVELOPMENT

This work was supported by Ministry of SMEs and Startups grant funded by Korea Technology and Information Promotion Agency for SMEs (TIPA). (Project Unique Number: 1425182152, Project Number: RS-2023-00302523, Research Program Name: Startup Growth Technology Development (R&D), Research Project Title: Low-Code Based Low-Power Semiconductor Solution, Executing Organization: ITDA Semiconductor, Research Period: July 1, 2023 – June 30, 2026) Meanwhile, in all the aspects of the inventive concept, there is no property interest in the government of the Republic of Korea.

### TECHNICAL FIELD

The present disclosure relates to a clock divider and a method of controlling the same, and more specifically, to a clock divider and a method of controlling the same to ensure that an output clock of the clock divider is in a low level state during a retention signal transition period such that a retention operation can be performed properly.

### BACKGROUND

A system on chip (SoC) refers to a technology for integrating various functional blocks such as a central processing unit (CPU), a memory, an interface, a digital signal processing circuit, and an analog signal processing circuit into a single semiconductor integrated circuit to implement a computer system or another electronic system, or an integrated circuit (IC) integrated according to the technology. SoC is developing into a more complex system that includes various functional blocks such as a processor, multimedia, graphics, an interface, and security blocks. In general, clock design is important in a system on chip.

FIG. 1 is a diagram showing a case in which a clock divider divides a clock input by 8 to generate a clock output. In clock design, a clock divider used in a clock tree generally operates an internal counter depending on how many divisions the clock is to be divided into, and divides the clock by creating a clock output edge whenever counting by the counter ends.

FIG. 2 is a diagram showing a case in which an output clock output by the clock divider is in a low level state at the moment when an input clock is gated. FIG. 3 is a diagram showing a case in which an output clock output by the clock divider is in a high level state at the moment when an input clock is gated. In cases where it is necessary to retain a power domain within a semiconductor system, there is a constraint that the clock input to a retention flip-flop must become a low level during a retention signal transition period.

Flip-flops having a retention function can retain stored data even when the power is off, which is especially useful in applications where power saving is important. Retention flip-flops can retain data when the power is off or upon entering a low power mode, reducing the power consumption of the entire system, and can restore data when the power is turned on again, ensuring data integrity.

As shown in FIG. 2, in the process of performing clock division of 8, if the count value of the counter for clock division is 4, 5, 6, or 7 at the moment when the input clock is gated (GT), the output clock becomes a low level state. If the condition is to simply stop clock toggle, clock gating can be performed by integrated clock gating (ICG), but if clock gating is performed in a clock divider equipped with a counter, the output clock may stop at a high level instead of a low level depending on the count state of the counter in a cycle.

As in the example of FIG. 3, if the counter for clock division operates in a period in which the output clock is at a high level, that is, in a period in which the count value of the counter is 0, 1, 2, or 3, at the moment when the input clock is gated, the output clock stops at a high level. In this way, even if the input clock is gated, the output clock may stop at a high level instead of a low level depending on the counting state of the counter.

If there are flip-flops that operate by receiving an output clock from a clock divider and these flip-flops are required to be retained, the clocks of the flip-flops must be at a low level during a retention signal transition period. However, if the output clock of the clock divider is not guaranteed to be at a low level, retention cannot be properly performed for the flip-flops. This problem can be a factor that restricts the degree of freedom in clock design.

### SUMMARY

In view of the above, the present disclosure provides a clock divider and a method of controlling the same to ensure that an output clock of the clock divider is in a low level state during a retention signal transition period such that a retention operation can be performed smoothly.

In addition, the present disclosure provides a clock divider and a method of controlling the same to maintain a clock output duty constant regardless of timing of changing a divide value.

In addition, the present disclosure enables all flip-flops that receive the output of the clock divider to be designed without being restricted by the duty and enables the divide value to be changed in various ways without causing a problem of deterioration in the clock duty quality.

The aspects to be achieved by embodiments of the present disclosure are not limited to the aspects described above, and other aspects can be inferred from the following embodiments.

A clock divider according to an aspect of the present disclosure includes a counter configured to count an input clock and generate a counter output for dividing the input clock, an output clock generator configured to generate clock edges according to the counter output and generate an output clock divided from the input clock, and a state machine configured to control the counter such that the output clock is switched to a low level in a retention signal transition period according to a clock low request from a power management unit.

Based on input of the clock low request, the state machine may be configured to wait until a count value of the counter reaches a counter expiration value corresponding to a divide value, and stop an operation of the counter such that the output clock remains at the low level based on the count value of the counter reaching the counter expiration value corresponding to the divide value.

Based on input of the clock low request, the state machine may be configured to determine whether the output clock output by the output clock generator is in a low level state, stop the operation of the counter such that the output clock remains at the low level based on the output clock being in the low level state, and maintain the operation of the counter until the output clock enters the low level state based on the output clock being in a high level state.

Based on input of the clock low request, the state machine may be configured to determine whether the count value of the counter is within a low level count range in which the output clock satisfies the low level, stop the operation of the counter such that the output clock remains at the low level based on the count value of the counter being within the low level count range, and maintain the operation of the counter until the count value of the counter reaches the low level count range based on the count value of the counter not reaching the low level count range.

Based on input of the clock low request, the state machine may be configured to compare the count value of the counter with a count setting value that is half of the counter expiration value corresponding to the divide value, maintain the operation of the counter until the count value reaches the count setting value based on the count value of the counter not reaching the count setting value, and stop the operation of the counter based on the count value of the counter reaching the count setting value and the output clock entering the low level state.

The output clock may be input to flip-flops, and the flip-flops may be retained based on the output clock in the low level state being ensured.

Based on the divide value being changed, the state machine may be configured to update the counter to a second counter expiration value corresponding to the changed divide value depending on whether a first counter expiration value corresponding to the divide value before being changed has expired.

Based on the divide value being changed, the state machine may be configured to compare the first counter expiration value corresponding to the divide value before being changed with the count value of the counter to determine whether counting of the first counter expiration value expires, wait without updating the second counter expiration value corresponding to the changed divide value based on the count value of the counter not reaching the first counter expiration value, and update the counter to the second counter expiration value at a moment at which the count value of the counter reaches the first counter expiration value.

According to an aspect of the present disclosure, there is provided a semiconductor system including the clock divider, one or more flip-flops configured to receive an output clock divided from an input clock by the clock divider and operate according to the output clock within a power domain, and a power management unit configured to output a clock low request to a state machine of the clock divider for retention.

The power management unit may be configured to output a retention signal to the flip-flops based on the output clock in a low level state being ensured according to the clock low request.

According to an aspect of the present disclosure, there is provided a method of controlling an operation of a clock divider including a counter, an output clock generator, and a state machine, the method including generating a counter output for dividing an input clock by counting the input clock by the counter, generating clock edges according to the counter output by the output clock generator to generate an output clock divided from the input clock, and controlling the counter by the state machine such that the output clock is switched to a low level in a retention signal transition period according to a clock low request from a power management unit.

The controlling the counter may include waiting until a count value of the counter reaches a counter expiration value corresponding to a divide value, and stopping the operation of the counter such that the output clock remains at the low level based on the count value of the counter reaching the counter expiration value corresponding to the divide value.

The controlling the counter may include determining whether the output clock output by the output clock generator is in a low level state, stopping the operation of the counter such that the output clock remains at the low level based on the output clock being in the low level state, and maintaining the operation of the counter until the output clock enters the low level state based on the output clock being in a high level state.

The controlling the counter may include determining whether the count value of the counter is within a low level count range in which the output clock satisfies the low level, stopping the operation of the counter such that the output clock remains at the low level based on the count value of the counter being within the low level count range, and maintaining the operation of the counter until the count value of the counter reaches the low level count range based on the count value of the counter not reaching the low level count range.

The controlling the counter may include comparing the count value of the counter with a count setting value that is half of the counter expiration value corresponding to the divide value, maintaining the operation of the counter until the count value of the counter reaches the count setting value based on the count value of the counter not reaching the count setting value, and stopping the operation of the counter based on the count value of the counter reaching the count setting value and the output clock entering the low level state.

The method according to an aspect of the present disclosure may further include, based on the divide value being changed, updating the counter, by the state machine, to a second counter expiration value corresponding to the changed divide value depending on whether a first counter expiration value corresponding to the divide value before being changed has expired.

The updating may include comparing the first counter expiration value corresponding to the divide value before being changed with the count value of the counter to determine whether counting of the first counter expiration value has expired, waiting without updating the second counter expiration value corresponding to the changed divide value based on the count value of the counter not reaching the first counter expiration value, and updating the counter to the second counter expiration value at a moment at which the count value of the counter reaches the first counter expiration value.

The method according to an aspect of the present disclosure may further include receiving an output clock divided from an input clock by the clock divider, by one or more flip-flops to operate in a power domain, outputting the clock low request from the power management unit to the state machine of the clock divider for retention, and outputting a retention signal to the flip-flops by the power management unit based on the output clock in the low level state being ensured according to the clock low request.

According to an aspect of the present disclosure, a non-transitory computer-readable recording medium storing a computer program for executing the clock divider control method is provided.

### ADVANTAGEOUS EFFECTS

According to an embodiment of the present disclosure, it is possible to provide a clock divider and a method of controlling the same to ensure that an output clock of the clock divider is in a low level state during a retention signal transition period such that a retention operation can be performed properly.

In addition, according to an embodiment of the present disclosure, it is possible to provide a clock divider and a method of controlling the same to maintain a clock output duty constant regardless of timing of changing a divide value.

In addition, according to an embodiment of the present disclosure, it is possible to design all flip-flops that receive the output of the clock divider without being restricted by the duty and change the divide value without causing a problem of deterioration in the clock duty quality.

### BRIEF DESCRIPTION OF THE DRAWINGS

FIG. 1 is a diagram showing a case in which a clock divider divides a clock input by 8 to generate a clock output.

FIG. 2 is a diagram showing a case in which an output clock output by a clock divider is in a low level state at the moment when an input clock is gated.

FIG. 3 is a diagram showing a case in which an output clock output by a clock divider is in a high level state at the moment when an input clock is gated.

FIG. 4 is a configuration diagram of a clock divider according to an embodiment of the present disclosure.

FIG. 5 is a flowchart showing an operation of a state machine constituting the clock divider and a clock divider control method according to an embodiment of the present disclosure.

FIG. 6 is a flowchart of a clock divider control method according to an embodiment of the present disclosure.

FIG. 7 is a flowchart of a clock divider control method according to another embodiment of the present disclosure.

FIG. 8 is a diagram illustrating the clock divider control method according to the embodiment of FIG. 7.

FIG. 9 is a conceptual diagram illustrating a computing device for executing a clock division method according to an embodiment of the present disclosure.

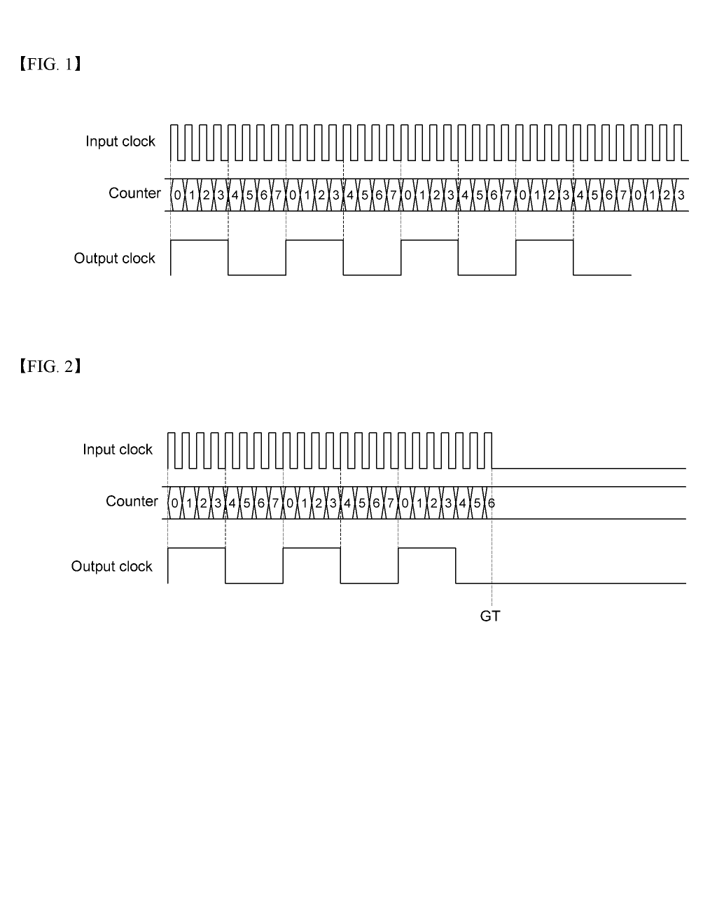

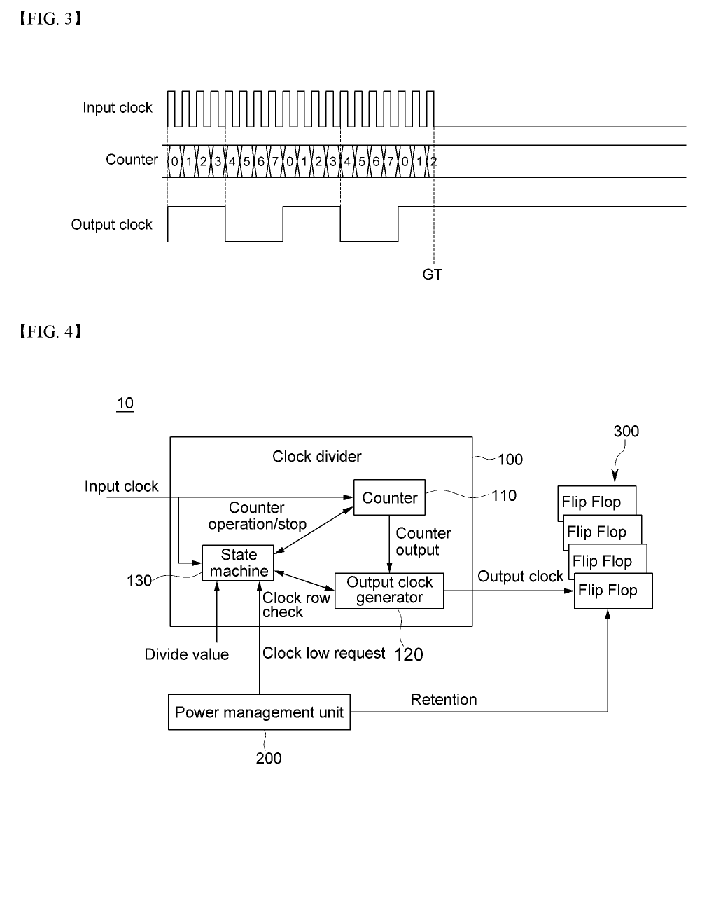

### DETAILED DESCRIPTION

Hereinafter, specific details for implementing the present disclosure will be described in detail with reference to the attached drawings. However, in the following description, a detailed description of known functions and configurations incorporated herein will be omitted when it may obscure the subject matter of the present disclosure. In the attached drawings, the same reference numbers will be used to refer to the same or like parts. In the description of the embodiments below, redundant descriptions of identical or corresponding components may be omitted. However, even if descriptions of components are omitted, it is not intended that such components are not included in any embodiment.

The advantages and features of the embodiments disclosed in this specification, and the methods for achieving the same will become clear with reference to the embodiments described below together with the attached drawings. However, the present disclosure is not limited to the embodiments disclosed below, but may be implemented in various different forms, and the embodiments are only provided to fully inform those skilled in the art of the scope of the present disclosure.

The terms used in this specification will be briefly explained, and the disclosed embodiments will be described in detail. The terms used in this specification are selected from the most widely used general terms possible while considering the functions of the present disclosure, but they may vary depending on the intention of engineers working in the relevant field, precedents, or the emergence of new technologies. In addition, in certain cases, there are terms arbitrarily selected by the applicant, and in this case, the meanings thereof will be described in detail in the description of the disclosure. Therefore, the terms used in the present disclosure should be defined based on the meanings of the terms and the overall contents of the present disclosure, rather than simply the names of the terms.

In this specification, singular expressions include plural expressions unless the context clearly specifies that they are singular. In addition, plural expressions include singular expressions unless the context clearly specifies that they are plural. When a part of the specification is said to include a certain component, this does not mean that other components are excluded, but rather that other components may be included, unless otherwise specifically stated. In the present disclosure, the terms “comprise” “comprising”, and the like may indicate that features, steps, operations, elements, and/or components are present, and these terms do not exclude the addition of one or more other functions, steps, operations, elements, components, and/or combinations thereof.

In the present disclosure, when a particular component is referred to as being “coupled to”, “combined with,” “connected to”, “associated with”, or “reacted with” another particular component, the particular component may be directly coupled to, combined with, connected to, associated with, or reacted with the other component, but is not limited thereto. For example, one or more intermediate components may be present between the particular component and the other component. Additionally, in the present disclosure, “and/or” may include each of one or more of listed items, or a combination of at least some of listed items. In the present disclosure, the terms “first”, “second”, etc. are used to distinguish a specific component from other components, and the components described above are not limited by these terms. For example, the “first” component may be used to refer to an element of the same or similar form as the “second” component.

A clock divider according to an embodiment of the present disclosure includes a state machine that controls a counter such that an output clock output from the clock divider 100 is in a low level during a retention signal transition period according to a clock low request of a power management unit. Accordingly, it is possible to ensure that the output clock of the clock divider is in a low level state in the retention signal transition period such that a retention operation can be performed properly.

The retention signal transition period may be a period in which a general mode is switched to a retention mode or a period in which the retention mode is switched to the general mode. The retention mode may be a mode in which data stored in a flip-flop is maintained in a power-off state or a low-power state. When the retention mode is switched to the general mode and thus the power is turned on again or switched to a general power mode (a mode in which the power is higher than the power in the low-power mode), the flip-flop maintains the data stored at the time of switching to the retention mode.

FIG. 4 is a configuration diagram of a clock divider according to an embodiment of the present disclosure. Referring to FIG. 4, the clock divider 100 according to the embodiment of the present disclosure may include a counter 110, an output clock generator 120, and a state machine 130. The clock divider 100 according to the embodiment of the present disclosure includes the state machine 130 that controls the counter 110 such that the output clock of the clock divider 100 is in a low level in a retention signal transition period according to a clock low request from a power management unit 200.

The counter 110 may count input clocks and generate a counter output based on a count of a counter expiration value corresponding to a clock divide value. The counter 110 may compare the counter expiration value corresponding to the divide value with an input clock count value of the counter 110 to generate a counter output. When the divide value is N (N being an integer equal to or greater than 2), the counter 110 may output a counter output to the output clock generator 120 whenever the value N/2 is counted.

For example, if the divide value is 8, the counter 110 may generate a first counter output at the moment when four input clocks from the first clock to the fourth clock are counted and output the first counter output to the output clock generator 120, and then generate a second counter output at the moment when four input clocks from the fifth clock to the eighth clock are counted and output the second counter output to the output clock generator 120.

As another example, if the divide value is 4, the counter 110 may generate a first counter output at the moment when two input clocks from the first clock and the second clock are counted and output the first counter output to the output clock generator 120, and then generate a second counter output at the moment when two input clocks from the third clock and the fourth clock are counted and output the second counter output to the output clock generator 120.

When the divide value is 8, the counter expiration value set for the counter 110 may be 8, and when the divide value is 4, the counter expiration value set for the counter 110 may be 4. When the divide value is N, the counter expiration value set for the counter 110 may be N. That is, when the divide value is N, the counter expiration value set for the counter 110 is based on starting counting from 1, and when the input clock is counted N times, the counter expiration output can be input to the output clock generator 120.

When the divide value is N, the counter 110 may generate a first counter output at the moment when N/2 clocks out of N input clocks are counted and output the first counter output to the output clock generator 120, and then generate a second counter output at the moment when N/2 clocks of the input clocks are counted again and output the second counter output to the output clock generator 120. The output clock generator 120 may generate output clocks divided from the input clocks according to the counter outputs (first counter output and second counter output) of the counter 110.

The first counter output may be a signal that causes the output clock generator 120 to generate a falling edge (or rising edge) of the output clock, and the second counter output may be a signal that causes the output clock generator 120 to generate a rising edge (or falling edge) of the output clock. The output clock generator 120 may repeatedly generate rising edges and falling edges according to the counter output that is output from the counter 110 whenever the counter 110 counts a value corresponding to half of the divide value, thereby generating and outputting the output clock divided from the input clock.

When the divide value is 8, the clock cycle of the output clock may be 8 times the reference clock cycle of the input clock. In this case, the frequency of the output clock becomes 1/8 of the frequency of the input clock. As another example, when the divide value is 4, the clock cycle of the output clock may be 4 times the reference clock cycle of the input clock. In this case, the frequency of the output clock becomes 1/4 of the frequency of the input clock. When the divide value is N (N being an integer equal to or greater than 2), the clock cycle of the output clock becomes N times the reference clock cycle of the input clock, and the frequency of the output clock becomes 1/N of the frequency of the input clock.

When the divide value is changed, the counter 110 may generate a counter output based on a count of a first counter expiration value corresponding to the divide value before being changed, and may generate a counter output based on a count of a second counter expiration value corresponding to the changed divide value. For example, when the divide value is changed from 8 to 4, the divide value before being changed is 8, and the changed divide value is 4. As another example, when the divide value is changed from 4 to 8, the divide value before being changed is 4, and the changed divide value is 8. The divide value may preferably be a multiple of 2, but is not necessarily limited thereto. In addition, various divide values may be applied in addition to 4 and 8.

In order to prevent an unintended change in a duty ratio due to change in the divide value, the state machine 130 may control update of the counter expiration value based on the count value of the counter 110 and the counter expiration value corresponding to the divide value before being changed. When the divide value is changed, the state machine 130 may update the counter to the second counter expiration value corresponding to the changed divide value depending on whether the first counter expiration value has expired. The first counter expiration value may be the counter expiration value corresponding to the first divide value that is the divide value before being change, and the second counter expiration value may be the counter expiration value corresponding to the second divide value that is the changed divide value. For example, when the divide value is changed from 8 to 4, the first counter expiration value may be 8, and the second counter expiration value may be 4.

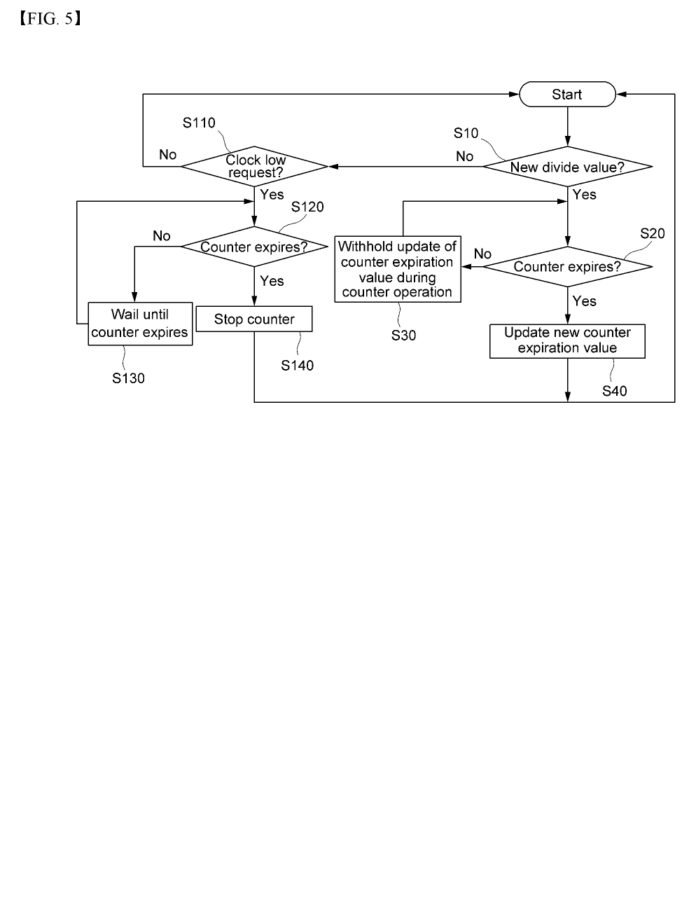

FIG. 5 is a flowchart showing the operation of the state machine constituting the clock divider and a clock divider control method according to an embodiment of the present disclosure. When a divide value is changed, the state machine 130 may compare a first counter expiration value (a previous counter expiration value before the divide value is changed) corresponding to the divide value before being changed with a count value of the counter to determine whether counting of the first counter expiration value has expired (S10 and S20). If the count value of the counter 110 has not reached the first counter expiration value, the state machine 130 may wait without updating a second counter expiration value (a new counter expiration value) corresponding to the changed divide value (S30). The state machine 130 may update the counter expiration value of the counter 110 to the second counter expiration value at the moment when the count value of the counter 110 reaches the first counter expiration value (S40).

In this way, when the divide value is changed, the state machine 130 waits without updating the counter expiration value corresponding to the changed divide value until the counter expiration value corresponding to the divide value before being changed is counted, and then, at the moment when counting of the divide value before being changed by the counter 110 is completed (the moment when the first counter expiration value expires), the state machine 130 may update the counter expiration value (the second counter expiration value) corresponding to the changed divide value for the counter 110.

That is, the state machine 130 may withhold the update of the counter expiration value corresponding to the changed divide value until the clock duty ratio with respect to the divide value before being changed becomes identical to the clock duty ratio with respect to the changed divide value. In other words, the state machine 130 may withhold the update of the counter expiration value by the number of clocks corresponding to the difference between the first counter expiration value before the divide value of the counter 110 is changed and the counting value of the counter at the time when the divide value is changed.

For example, if the divide value is changed from 8 to 4 in a state in which the counter 110 has counted the fifth input clock, the first counter expiration value is 8 and the current count value of the counter 110 is 5, and thus the state machine 130 waits until the counter 110 additionally counts 3 input clocks (8 clocks - 5 clocks), and then when the counter 110 counts the remaining 3 clocks and enters a counter expiration state, updates the counter expiration value from 8 to 4. If the changed divide value is N (N being an integer equal to or greater than 2), the state machine 130 may set the counter expiration value of the counter 110 to a count value N corresponding to the number N of clocks.

The power management unit 200 may control the power supplied to the IP blocks. For example, when the system-on-chip enters a standby mode, the power management unit 200 may cut off the power provided to each IP block, thereby reducing power consumption of the system-on-chip. The power management unit 200 can output a clock low request to the state machine 130 of the clock divider 110 for retention.

The state machine 130 may control the counter 110 such that output clocks become a low level in a retention signal transition period according to the clock low request from the power management unit 200. When the state machine 130 receives the clock low request from the power management unit 200 (step S110 in FIG. 5), the state machine 130 may determine whether the count value of the counter 110 has reached the counter expiration value corresponding to the divide value (whether counting has expired) and wait until the count value of the counter 110 reaches the counter expiration value corresponding to the divide value (steps S120 and S130 in FIG. 5). When the count value of the counter 110 has reached the counter expiration value corresponding to the divide value, the state machine 130 may stop the operation of the counter 110 such that the output clocks remain at a low level (steps S120 and S140 in FIG. 5).

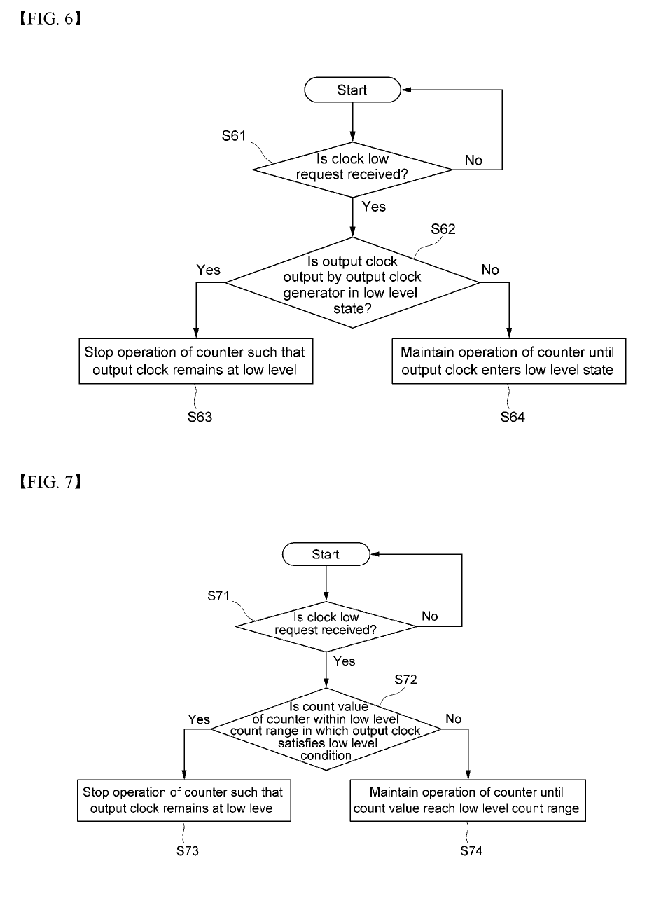

FIG. 6 is a flowchart of a clock divider control method according to an embodiment of the present disclosure. Referring to FIGS. 4 and 6, when the state machine 130 receives a clock low request from the power management unit 200 (step S61), the state machine 130 determines whether the output clock output by the output clock generator 120 is in a low level state (step S62), and if the output clock output by the output clock generator 120 is in a low level state, immediately stops the operation of the counter 110 such that the output clock remain at the low level (step S63). If the output clock output by the output clock generator 120 is in a high level state, the state machine 130 may maintain the operation of the counter 110 until the output clock becomes a low level state (step S64), and at the moment when the output clock becomes a low level state, stop the operation of the counter 110 such that the output clock remains at the low level.

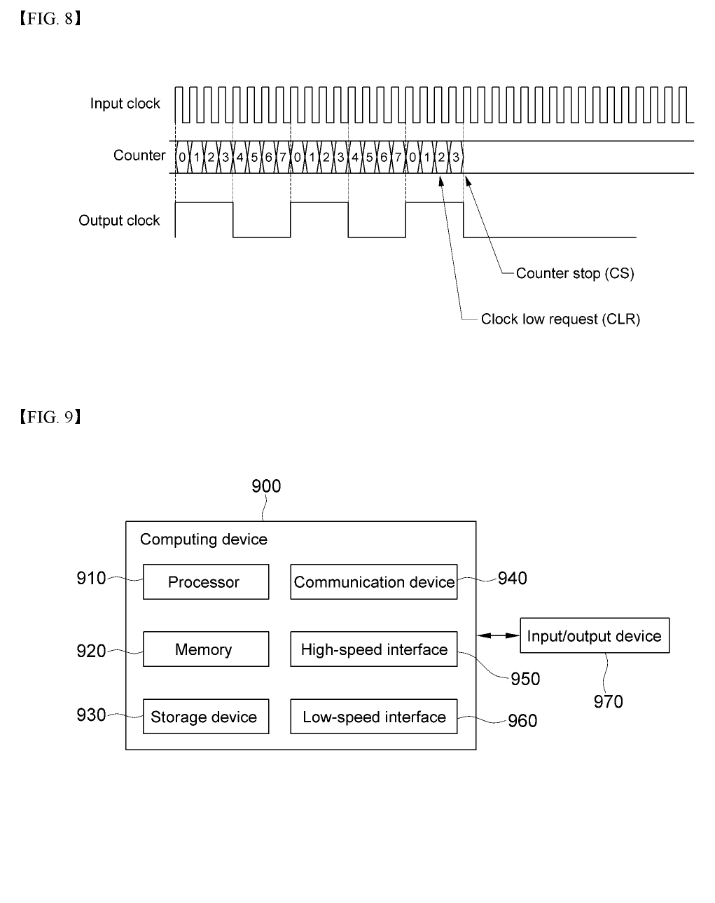

FIG. 7 is a flowchart of a clock divider control method according to another embodiment of the present disclosure. FIG. 8 is a diagram illustrating the clock divider control method according to the embodiment of FIG. 7. Referring to FIGS. 4, 7, and 8, when the state machine 130 receives a clock low request from the power management unit 200 (step S71), the state machine 130 may determine whether the count value of the counter 110 is within a low level count range in which the output clock satisfies a low level (step S72).

The state machine 130 may stop the operation of the counter 110 such that the output clock remains at a low level when the count value of the counter 110 is within the low level count range (step S73). When the count value of the counter 110 has not reached the low level count range, the state machine 130 may maintain the operation of the counter 110 until the counter 110 reaches the low level count range (step S74). Through the above-described process, the power management unit 200 can output a retention signal to flip-flops when it is ensured that the output clock of the clock divider 100 is in a low level state according to the clock low request.

For example, when the divide value is 8, the state machine 130 can immediately stop the operation of the counter 110 such that the output clock remains at the low level if the count value of the counter 110 is within the low level count range, that is, if the count value of the counter 110 when the first count number is 1 is 5 to 8 (4 to 7 when the first count number is 0).

On the other hand, the state machine 130 can maintain the operation of the counter 110 if the count value of the counter 110 is not within the low level count range, that is, if the count value of the counter 110 when the first count number is 1 is 1 to 4 (0 to 3 when the first count number is 0), and stop the operation of the counter 110 if the count value of the counter 110 reaches the low level count range.

Although the state machine 130 may maintain the operation of the counter 110 until the count value of the counter 110 reaches the counter expiration value when the count value of the counter 110 has not reached the low level count range, the state machine 130 may stop the operation of the counter 110 first when the output clock is switched to the low level before the count value of the counter 110 reaches the counter expiration value. In this case, the state machine 130 may maintain the operation of the counter 110 and stop the operation of the counter 110 at the moment when the counter 110 counts more than half of the counter expiration value.

In the example of FIG. 8, when an output clock is generated by dividing an input clock by 8, if a clock low request CLR occurs in a state in which the count value of the counter 110 has not reached half of the counter expiration value, the state machine 130 may maintain the operation of the counter 110 only until the count value of the counter 110 reaches half of the counter expiration value, and stop the operation of the counter 110 at a counter operation stop timing CS at the moment when the count value of the counter 110 reaches half of the counter expiration value, or between the moment when the count value of the counter 110 reaches half of the counter expiration value and the time when the count value reaches the counter expiration value, that is, when the count value reaches 4, 5, 6, 7, and 8 corresponding to the low level count range of the counter 110 when the first count number is 1 (3, 4, 5, 6, and 7 when the first count number is 0).

As described above, when the clock low request is received from the power management unit 200, the state machine 130 may compare the count value of the counter 110 with a count setting value, which is half of the counter expiration value corresponding to the divide value, and if the count value of the counter 110 does not reach the count setting value, maintain the operation of the counter 110 until the count setting value reaches the count setting value.

If the count value of the counter 110 reaches the count setting value and the output clock becomes a low level state, the state machine 130 may stop the operation of the counter 110. The output clock generated by the output clock generator 120 may be input to one or more flip-flops 300. According to an embodiment of the present disclosure, the flip-flops 300 can be retained when it is ensured that the output clock is in a low level state.

According to the embodiment of the present disclosure as described above, by ensuring a low level state of the output clock of the clock divider in a retention signal transition period, the retention operation of a flip-flop can be performed properly and correctly. In addition, since the low level of the output clock of the clock divider can be ensured during retention, the output clock of the clock divider can be used as is in the retention logic, thereby increasing the freedom of clock design of the semiconductor system.

When the divide value is changed, the state machine 130 can update the counter 110 to the second counter expiration value corresponding to the changed divide value depending on whether the first counter expiration value corresponding to the divide value before being changed has expired. When the divide value is changed, the state machine 130 can compare the first counter expiration value corresponding to the divide value before being changed with the count value of the counter 110 to determine whether counting of the first counter expiration value has expired.

The state machine 130 can wait without updating the second counter expiration value (new counter expiration value) corresponding to the changed divide value if the count value of the counter 110 does not reach the first counter expiration value (the previous counter expiration value before the divide value is changed), and update the counter 110 to the second counter expiration value at the moment when the count value of the counter 110 reaches the first counter expiration value.

FIG. 9 is a conceptual diagram illustrating a computing device for executing a clock division method according to an embodiment of the present disclosure. An exemplary computing device 900 for performing the above-described method and/or embodiment will be described. According to one embodiment, the computing device 900 may be implemented using hardware and/or software configured to interact with a user. The computing device 900 may include, but is not limited to, a laptop, a desktop, a workstation, a personal digital assistant, a server, a blade server, a main frame, etc. The components of the computing device 900 described above, the connection relationships thereof, and functions thereof are intended to be exemplary and are not intended to limit the implementations of the present disclosure described and/or claimed herein.

The computing device 900 includes a processor 910, a memory 920, a storage device 930, a communication device 940, a high-speed interface 950 connected to the memory 920 and a high-speed expansion port, and a low-speed interface 960 connected to a low-speed bus and the storage device. The components 910, 920, 930, 940, 950, and 960 may be interconnected using various buses and may be mounted on the same main board or may be mounted and connected in another suitable manner. The processor 910 may be configured to process instructions of a computer program by performing basic arithmetic, logic, and input/output operations. For example, the processor 910 may process instructions stored in the memory 920 and the storage device 930 and/or instructions executed within the computing device 900, and display graphic information on an external input/output device 970, such as a display device, coupled to the high-speed interface 950.

The communication device 940 may provide a configuration or function for the input/output device 970 and the computing device 900 to communicate with each other through a network, and may provide a configuration or function for supporting the input/output device 970 and/or the computing device 900 to communicate with other external devices. For example, a request or data generated by a processor of an external device according to any program code may be transmitted to the computing device 900 through a network under the control of the communication device 940. Conversely, a control signal or command provided under the control of the processor 910 of the computing device 900 may be transmitted to another external device through the communication device 940 and a network.

Although the computing device 900 is illustrated as including one processor 910, one memory 920, etc., the present disclosure is not limited thereto, and the computing device 900 may be implemented using multiple memories, multiple processors, and/or multiple buses, etc. In addition, although one computing device 900 is illustrated, the present disclosure is not limited thereto, and multiple computing devices may interact and perform operations necessary to execute the method described above.

The memory 920 may store information within the computing device 900. According to an embodiment, the memory 920 may be composed of a volatile memory unit or multiple memory units. Additionally or alternatively, the memory 920 may be composed of a non-volatile memory unit or multiple memory units. In addition, the memory 920 may be configured as a computer-readable medium, such as a magnetic disk or an optical disc. In addition, the memory 920 may store an operating system and at least one program code and/or instruction.

The storage device 930 may be one or more large-capacity storage devices for storing data for the computing device 900. For example, the storage device 930 may be a computer-readable medium including, or configured to include, a magnetic disk such as a hard disk, a removable disk, an optical disc, a semiconductor memory device such as an erasable programmable read-only memory (EPROM), an electrically erasable PROM (EEPROM), a flash memory device, a CD-ROM, and a DVD-ROM disk. In addition, a computer program may be tangibly implemented in such a computer-readable medium.

The high-speed interface 950 and the low-speed interface 960 may be means for interacting with the input/output device 970. For example, the input device may include devices such as a camera including an audio sensor and an image sensor, a keyboard, a microphone, and a mouse, and the output device may include devices such as a display, a speaker, and a haptic feedback device. In another example, the high-speed interface 950 and the low-speed interface 960 may be means for interfacing with a device in which components and functions for performing input and output are integrated, such as a touchscreen.

In an embodiment, the high-speed interface 950 may manage bandwidth-intensive operations with respect to the computing device 900, whereas the low-speed interface 960 may manage less bandwidth-intensive operations than the high-speed interface 950, but such functional allocation is merely exemplary. In an embodiment, the high-speed interface 950 may be coupled to the memory 920, the input/output device 970, and high-speed expansion ports that may accommodate various expansion cards (not shown). Additionally, the low-speed interface 960 may be coupled to the storage device 930 and a low-speed expansion port. Additionally, the low-speed expansion port, which may include various communication ports (e.g., USB, Bluetooth, Ethernet, and wireless Ethernet), may be coupled to one or more input/output devices 970, such as a keyboard, a pointing device, and a scanner, or a networking device, such as a router or a switch via a network adapter.

The computing device 900 may be implemented in a number of different forms. For example, the computing device 900 may be implemented as a standard server, or may be implemented as a group of such standard servers. Additionally or alternatively, the computing device 900 may be implemented as part of a rack server system, or may be implemented as a personal computer, such as a laptop computer. In this case, components of the computing device 900 may be combined with other components within any mobile device (not shown). The computing device 900 may include one or more other computing devices, or may be configured to communicate with one or more other computing devices.

Although the input/output device 970 is illustrated as not being included in the computing device 900, the present disclosure is not limited thereto, and the input/output device 970 may be integrated with the computing device 900. In addition, although the high-speed interface 950 and/or the low-speed interface 960 are illustrated as elements configured separately from the processor 910, the present disclosure is not limited thereto, and the high-speed interface 950 and/or the low-speed interface 960 may be configured to be included in the processor 910.

The above-described methods and/or various embodiments may be realized by digital electronic circuits, computer hardware, firmware, software, and/or a combination thereof. The various embodiments of the present disclosure may be executed by a data processing device, for example, one or more programmable processors and/or one or more computing devices, or implemented as a computer-readable medium and/or a computer program stored in a computer-readable medium. The above-described computer program may be written in any form of programming language, including compiled or interpreted languages, and may be distributed in any form, such as a standalone program, a module, and a subroutine. The computer program may be distributed through a single computing device, multiple computing devices connected through the same network, and/or multiple computing devices distributed to be connected through multiple different networks.

The above-described methods and/or various embodiments may be performed by one or more processors configured to execute one or more computer programs that process, store, and/or manage any function, etc. by operating based on input data or generating output data. For example, the methods and/or various embodiments of the present disclosure may be performed by a special purpose logic circuit such as a field programmable gate array (FPGA) or an application specific integrated circuit (ASIC), and a device and/or a system for performing the methods and/or embodiments of the present disclosure may be implemented as a special purpose logic circuit such as an FPGA or an ASIC.

The one or more processors executing the computer program may include a general purpose or special purpose microprocessor and/or one or more processors of any kind of digital computing device. The processor may receive instructions and/or data from each of a read-only memory and a random access memory, or may receive instructions and/or data from the read-only memory and the random access memory. In the present disclosure, the components of the computing device performing the methods and/or embodiments may include one or more processors for executing instructions, and one or more memories for storing instructions and/or data.

According to an embodiment, the computing device may transmit/receive data to/from one or more large-capacity storage devices for storing data. For example, the computing device may receive data from a magnetic disk or an optical disc and transmit data thereto. A computer-readable medium suitable for storing instructions and/or data associated with a computer program may include, but is not limited to, any form of non-volatile memory, including semiconductor memory devices such as an erasable programmable read-only memory (EPROM), an electrically erasable PROM (EEPROM), and a flash memory device. For example, the computer-readable medium may include a magnetic disk, such as an internal hard disk or a removable disk, a photomagnetic disk, a CD-ROM, and a DVD-ROM disc.

To provide interaction with a user, the computing device may include, but is not limited to, a display device (e.g., a cathode ray tube (CRT), a liquid crystal display (LCD), or the like) for providing or displaying information to the user, and a pointing device (e.g., a keyboard, a mouse, a trackball, or the like) for enabling the user to provide input and/or commands to the computing device. That is, the computing device may further include any other types of devices for providing interaction with the user. For example, the computing device may provide any form of sensory feedback, including visual feedback, auditory feedback, and/or tactile feedback, to the user for interacting with the user. In this regard, the user may provide input to the computing device through various gestures, such as sight, voice, and motion.

In the present disclosure, various embodiments may be implemented in a computing device including a back-end component (e.g., a data server), a middleware component (e.g., an application server), and/or a front-end component. In this case, the components may be interconnected by any form or medium of digital data communication, such as a communication network. According to an embodiment, the communication network may be a wired network such as Ethernet, a wired home network (Power Line Communication), a telephone line communication device, or RS-serial communication, a wireless network such as a mobile communication network, a wireless LAN (WLAN), Wi-Fi, Bluetooth, or ZigBee, or a combination thereof. For example, the communication network may include a local area network (LAN), a wide area network (WAN), etc.

The computing device based on the exemplary embodiments described herein may be implemented using hardware and/or software configured to interact with a user, including a user device, a user interface (UI) device, a user terminal, or a client device. For example, the computing device may include a portable computing device such as a laptop computer. Additionally or alternatively, the computing device may include, but is not limited to, a personal digital assistant (PDA), a tablet computer, a game console, a wearable device, an IoT (Internet of Things) device, a virtual reality (VR) device, an augmented reality (AR) device, and the like. The computing device may further include other types of devices configured to interact with a user. Furthermore, the computing device may include a portable communication device (e.g., a mobile phone, a smartphone, a wireless cellular phone, and the like) suitable for wireless communication over a network, such as a mobile communication network. The computing device may be configured to wirelessly communicate with a network server using wireless communication technologies and/or protocols, such as Radio Frequency (RF), Microwave Frequency (MWF), and/or Infrared Ray Frequency (IRF).

The various embodiments including specific structural and functional details in the present disclosure are exemplary. Therefore, the embodiments of the present disclosure are not limited to those described above, and may be implemented in various other forms. In addition, the terms used in the present disclosure are intended to describe some embodiments and are not to be construed as limiting the embodiments. For example, singular words may be construed to include plural forms unless the context clearly indicates otherwise.

In the present disclosure, unless otherwise defined, all terms used in this specification, including technical or scientific terms, have the same meaning as commonly understood by a person skilled in the art to which such concepts belong. In addition, commonly used terms, such as terms defined in dictionaries, should be interpreted as having meanings consistent with the meanings in the context of the relevant technology.

Although the present disclosure has been described in connection with some embodiments herein, various modifications and changes may be made without departing from the scope of the present disclosure as understood by a person skilled in the art to which the present disclosure belongs. In addition, such modifications and changes should be considered to fall within the scope of the claims appended hereto.

[Detailed Description of Main Elements]

100: clock divider

110: counter

120: output clock generator

130: state machine

200: power management unit

300: flip-flop

900: computing device

910: processor

920: memory

930: storage device

940: communication device

950: high-speed interface

960: low-speed interface

970: external input/output device

What is claimed is:

1. A clock divider comprising:
a counter configured to count an input clock and generate a counter output for dividing the input clock;
an output clock generator configured to generate clock edges according to the counter output and generate an output clock divided from the input clock; and
a state machine configured to control the counter such that the output clock is in a low level during a retention signal transition period according to a clock low request from a power management unit.

2. The clock divider of claim 1, wherein, based on input of the clock low request, the state machine is configured to:
wait until a count value of the counter reaches a counter expiration value corresponding to a divide value; and
stop an operation of the counter such that the output clock remain at the low level based on the count value of the counter reaching the counter expiration value corresponding to the divide value.

3. The clock divider of claim 1, wherein, based on input of the clock low request, the state machine is configured to:
determine whether the output clock output by the output clock generator is in a low level state;
stop the operation of the counter such that the output clock remains at the low level based on the output clock being in the low level state; and
maintain the operation of the counter until the output clock enters the low level state based on the output clock being in a high level state.

4. The clock divider of claim 1, wherein, based on input of the clock low request, the state machine is configured to:
determine whether the count value of the counter is within a low level count range in which the output clock satisfies the low level;
stop the operation of the counter such that the output clock remains at the low level based on the count value of the counter being within the low level count range; and
maintain the operation of the counter until the count value of the counter reaches the low level count range based on the count value of the counter not reaching the low level count range.

5. The clock divider of claim 4, wherein, based on input of the clock low request, the state machine is configured to:
compare the count value of the counter with a count setting value that is half of a counter expiration value corresponding to a divide value;
maintain the operation of the counter until the count value reaches the count setting value based on the count value of the counter not reaching the count setting value; and
stop the operation of the counter based on the count value of the counter reaching the count setting value and the output clock entering a low level state.

6. The clock divider of claim 1, wherein the output clock is input to flip-flops, and the flip-flops are retained based on the output clock being ensured in a low level state.

7. The clock divider of claim 1, wherein, based on the divide value being changed, the state machine is configured to update the counter to a second counter expiration value corresponding to the changed divide value depending on whether a first counter expiration value corresponding to a divide value before being changed has expired.

8. The clock divider of claim 7, wherein, based on the divide value being changed, the state machine is configured to:
compare the first counter expiration value corresponding to the divide value before being changed with the count value of the counter to determine whether counting of the first counter expiration value expires;
wait without updating the second counter expiration value corresponding to the changed divide value based on the count value of the counter not reaching the first counter expiration value; and
update the counter to the second counter expiration value at a moment at which the count value of the counter reaches the first counter expiration value.

9. A semiconductor system comprising:
the clock divider according to claim 1;
one or more flip-flops configured to a receive an output clock divided from an input clock by the clock divider and operate according to the output clock within a power domain; and
a power management unit configured to output a clock low request to a state machine of the clock divider for retention.

10. The semiconductor system of claim 9, wherein the power management unit is configured to output a retention signal to the flip-flops based on the output clock in a low level state being ensured according to the clock low request.

11. A non-transitory computer-readable recording medium storing a computer program for executing a clock divider control method of controlling an operation of a clock divider including a counter, an output clock generator, and a state machine, wherein the clock divider control method comprises:
generating a counter output for dividing an input clock by counting the input clock by the counter;
generating clock edges according to the counter output by the output clock generator to generate an output clock divided from the input clock; and
controlling the counter by the state machine such that the output clock is in a low level during a retention signal transition period according to a clock low request from a power management unit.

12. The non-transitory computer-readable recording medium of claim 11, wherein the controlling the counter comprises:
waiting until a count value of the counter reaches a counter expiration value corresponding to a divide value; and
stopping the operation of the counter such that the output clock remains at the low level based on the count value of the counter reaching the counter expiration value corresponding to the divide value.

13. The non-transitory computer-readable recording medium of claim 11, wherein the controlling the counter comprises:
determining whether the output clock output by the output clock generator is in a low level state;
stopping the operation of the counter such that the output clock remains at the low level based on the output clock being in the low level state; and
maintaining the operation of the counter until the output clock enters the low level state based on the output clock being in a high level state.

14. The non-transitory computer-readable recording medium of claim 11, wherein the controlling the counter comprises:
determining whether a count value of the counter is within a low level count range in which the output clock satisfies the low level;
stopping the operation of the counter such that the output clock remains at the low level based on the count value of the counter being within the low level count range; and
maintaining the operation of the counter until the count value of the counter reaches the low level count range based on the count value of the counter not reaching the low level count range.

15. The non-transitory computer-readable recording medium of claim 14, wherein the controlling the counter comprises:
comparing the count value of the counter with a count setting value that is half of the counter expiration value corresponding to a divide value;
maintaining the operation of the counter until the count value of the counter reaches the count setting value based on the count value of the counter not reaching the count setting value; and
stopping the operation of the counter based on the count value of the counter reaching the count setting value and the output clock entering a low level state;

16. The non-transitory computer-readable recording medium of claim 11, wherein the output clock is input to flip-flops, and the flip-flops are retained based on the output clock being ensured in a low level state.

17. The non-transitory computer-readable recording medium of claim 11, wherein the clock divider control method further comprises:
based on a divide value being changed, updating the counter, by the state machine, to a second counter expiration value corresponding to the changed divide value depending on whether a first counter expiration value corresponding to the divide value before being changed has expired.

18. The non-transitory computer-readable recording medium of claim 17, wherein the updating comprises:
comparing the first counter expiration value corresponding to the divide value before being changed with the count value of the counter to determine whether counting of the first counter expiration value has expired;
waiting without updating the second counter expiration value corresponding to the changed divide value based on the count value of the counter not reaching the first counter expiration value; and
updating the counter to the second counter expiration value at a moment at which the count value of the counter reaches the first counter expiration value.

19. The non-transitory computer-readable recording medium of claim 11, wherein the clock divider control method further comprises:
receiving an output clock divided from an input clock by the clock divider, by one or more flip-flops to operate in a power domain;
outputting the clock low request from the power management unit to the state machine of the clock divider for retention; and
outputting a retention signal to the flip-flops by the power management unit based on the output clock being ensured in the low level state according to the clock low request.
